(19) United States
(12) Patent Application Publication
(10) Pub. No.: US 2025/0210420 A1
(43) Pub. Date: Jun. 26, 2025

(54) INTEGRATED CIRCUIT PACKAGES AND METHODS

(71) Applicant: Taiwan Semiconductor Manufacturing Co., Ltd., Hsinchu (TW)

(72) Inventors: Bang Li Wu, Hsinchu (TW); Ching Wang, Taichung City (TW); Chien-Chang Wang, Hsinchu (TW); Kuo-Chin Chang, Chiayi City (TW); Kathy Wei Yan, Hsinchu (TW); Jun He, Zhubei City (TW)

(21) Appl. No.: 18/636,609

(22) Filed: Apr. 16, 2024

Related U.S. Application Data
(60) Provisional application No. 63/614,704, filed on Dec. 26, 2023.

(51) Int. Cl. H01L 23/04; H01L 23/00; H01L 23/16; H01L 23/31; H01L 23/367; H01L 25/10

(52) U.S. Cl. CPC H01L 23/04; H01L 23/16; H01L 23/3675; H01L 24/08; H01L 24/32; H01L 24/83; H01L 25/105; H01L 23/3107; H01L 24/96; H01L 24/97; H01L 2224/08225; H01L 2224/32225; H01L 2224/83896; H01L 2224/96; H01L 2224/97; H01L 2225/1047; H01L 2924/1815

(57) ABSTRACT

An integrated circuit package and the method of forming the same are provided. An integrated circuit package may include a first die having a first substrate over a package substrate and a lid. A first channel may extend through the first substrate from a first sidewall of the first die to a second sidewall of the first die. The lid may include a top portion over the first die and a first bottom portion extending along the first sidewall of the first die. The first bottom portion may include a second channel connected to the first channel.

### PRIORITY CLAIM AND CROSS-REFERENCE

This application claims the benefit of U.S. Provisional Application No. 63/614,704, filed on Dec. 26, 2023, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 2, 3, 4A, 4B, 4C, 5, 6, 7, 8, 9, 10, 11, 12A, 12B, 12C, 13A, 13B, 13C, 13D, and 13E illustrate cross-sectional views and top-down views of intermediate processing steps in the formation of an integrated circuit package, in accordance with some embodiments.

FIGS. 14A, 14B, and 14C illustrate cross-sectional views of an integrated circuit package, in accordance with some embodiments.

FIGS. 15A and 15B illustrate cross-sectional views of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated circuit package with a lid having coolant fluid channels and the method of forming the same are provided. The integrated circuit package may comprise one or more integrated circuit dies and a lid. The lid may comprise a top portion over the one or more integrated circuit dies and bottom portions along sidewalls of the one or more integrated circuit dies. The lid may further comprise coolant fluid channels in the top portion and the bottom portions. The coolant fluid channels in the bottom portions may be connected to coolant fluid channels in the one or more integrated circuit dies. Since the coolant fluid may flow close to the hot-spots (e.g., devices) in the one or more integrated circuit dies, the heat generated in the one or more integrated circuit dies may be more effectively dissipated during the operation of the integrated circuit package, thereby improving the heat dissipation of the integrated circuit package. As a result, the performance and reliability of the integrated circuit package may be improved.

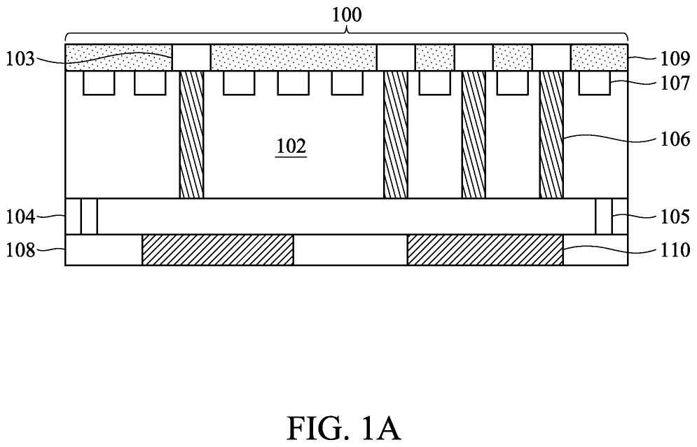

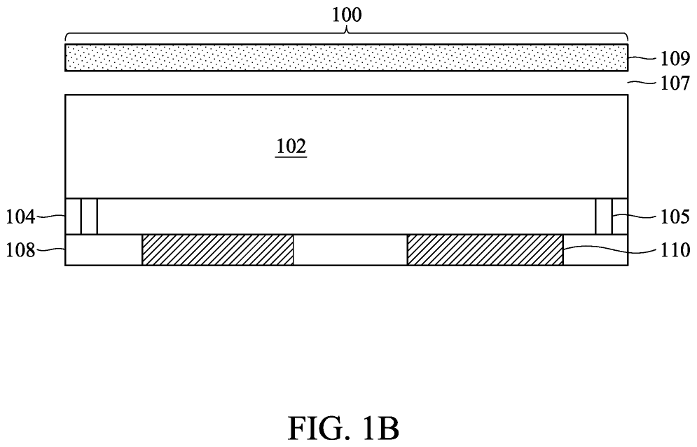

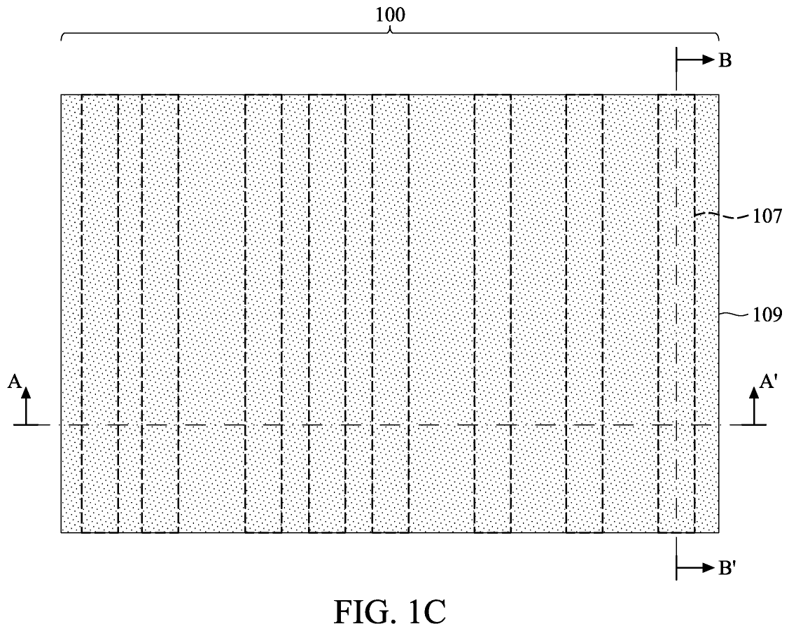

FIGS. 1A-13E illustrate intermediate processing steps in forming an integrated circuit package. In FIGS. 1A to 1C, a lower integrated circuit die 100 is shown. The cross-sectional view of the lower integrated circuit die 100 shown in FIG. 1A may be obtained along a reference cross-section AA′ shown in the top-down view of the lower integrated circuit die 100 in FIG. 1C. The cross-sectional view of the lower integrated circuit die 100 shown in FIG. 1B may be obtained along a reference cross-section BB′ shown in the top-down view of the lower integrated circuit die 100 in FIG. 1C.

The lower integrated circuit die 100 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or combinations thereof.

The lower integrated circuit die 100 may have a semiconductor substrate 102, such as doped or undoped silicon, an active layer of a semiconductor-on-insulator (SOI) substrate, or the like. The semiconductor substrate 102 may include other semiconductor materials, such as germanium, silicon carbide, gallium arsenic, gallium phosphide, indium phosphide, indium arsenide, indium antimonide, SiGe, GaAsP, AlInAs, AlGaAs, GaInAs, GaInP, and/or GaInAsP, or combinations thereof. Other substrates, such as multi-layered or gradient substrates, may also be used. The semiconductor substrate 102 may have an active surface (e.g., the surface facing downwards in FIGS. 1A and 1B), which may be called a front side, and an inactive surface (e.g., the surface facing upwards in FIGS. 1A and 1B), which may be called a back side. The back side of the semiconductor substrate 102 may also be referred to as a back side of the lower integrated circuit die 100 and the front side of the semiconductor substrate 102 may face a front side of the lower integrated circuit die 100.

Devices (not separately shown) may be disposed at the active surface of the semiconductor substrate 102. The devices may be active devices (e.g., transistors, diodes, etc.), capacitors, resistors, or the like. The devices may generate a large amount of heat during the operation of the lower integrated circuit die 100 and may create hot-spots in the lower integrated circuit die 100. An interconnect structure 104 may be disposed on the active surface of the semiconductor substrate 102. The interconnect structure 104 may interconnect the devices to form an integrated circuit. The interconnect structure 104 may comprise metallization patterns (not separately shown) in dielectric layers (not separately shown). The dielectric layers may be low-k dielectric layers. The metallization patterns may include metal lines and vias, which may be formed in the dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns may be electrically coupled to the devices. A seal ring 105 may extend through the interconnect structure 104 of the lower integrated circuit die 100. The seal ring 105 may encircle the metallization patterns of the corresponding interconnect structure 104 in a top-down view. The seal ring 105 may be formed of the same or similar material and by the same or similar process as the metallization patterns. The seal ring 105 may be electrically isolated from the devices.

Conductive vias 106 may be disposed in the semiconductor substrate 102. The conductive vias 106 may be electrically coupled to the metallization patterns of the interconnect structure 104. The conductive vias 106 may be referred to as through-substrate vias (TSV). Channels 107 may be disposed on the back side of the semiconductor substrate 102. The channels 107 may be openings in which coolant fluid may travel through to dissipate the heat generated in the lower integrated circuit die 100 during operation, as described in greater detail below. The channels 107 are shown in FIG. 1C in dotted lines for illustrative purposes. As shown in FIG. 1A, the channels 107 are disposed between neighboring conductive vias 106. As shown in FIGS. 1B and 1C, the channels 107 may extend in parallel through the semiconductor substrate 102 from one sidewall to an opposing sidewall. The channels 107 may be formed in the semiconductor substrate 102 by a suitable photolithography process. The number and arrangement of the channels 107 in FIGS. 1A, 1B, and 1C are provided as examples. Other numbers and arrangements of the channels 107 are also contemplated.

A cover 109 may be disposed on the back side of the semiconductor substrate 102 and cover the channels 107. The cover 109 may be adhered to the semiconductor substrate 102 by an adhesive (not separately shown), such as thermal interface material (TIM) or the like. The cover 109 may be formed of a same or similar material as the semiconductor substrate 102. In some embodiments, conductive pads 103 extend through the cover 109, and physically and electrically couple to the conductive vias 106, as shown in FIG. 1A. External connections may be made to the lower integrated circuit die 100 through the conductive pads 103. For such embodiments, the conductive pads 103 are omitted in FIG. 1C for illustrative purposes. In some embodiments, the conductive vias 106 may extend through the cover 109. External connections may be made to the lower integrated circuit die 100 through the conductive vias 106. For such embodiments, the conductive vias 106 are omitted in FIG. 1C for illustrative purposes.

A dielectric layer 108 may be disposed on the interconnect structure 104 at the front side of the lower integrated circuit die 100. The dielectric layer 108 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; or the like. The dielectric layer 108 may be formed by chemical vapor deposition (CVD), atomic layer deposition (ALD), or the like. One or more passivation layer(s) (not separately shown) may be disposed between the dielectric layer 108 and the interconnect structure 104. Conductive pads 110 may extend through the dielectric layer 108 and be electrically coupled to metallization patterns of the interconnect structure 104. External connections may be made to the lower integrated circuit die 100 through the conductive pads 110. The conductive pads 110 may be formed by a damascene process, such as a single damascene process, a dual damascene process, or the like. The conductive pads 110 may be formed of a conductive material, such as copper, aluminum, or the like, by a suitable coating process, such as plating or the like.

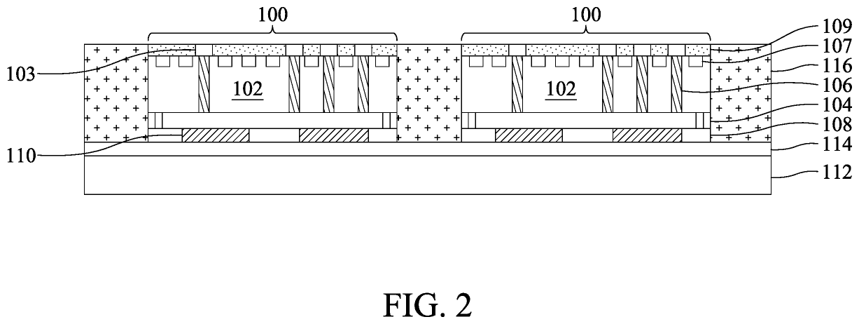

In FIG. 2, the lower integrated circuit dies 100 are attached to a carrier 112 by an adhesive 114 and a lower gap-fill layer 116 is formed around the lower integrated circuit dies 100. The layout of the lower integrated circuit dies 100 over the carrier 112 shown in FIG. 2 is provided as an example. Other layouts of the lower integrated circuit dies 100 are contemplated. The carrier 112 may be a semiconductor carrier, a glass carrier, a ceramic carrier, or the like. The carrier 112 may be a wafer. In some embodiments, the adhesive 114 is a thermal-release material, such as an epoxy-based light-to-heat-conversion (LTHC) release material, which loses its adhesive property when heated. In some embodiments, the adhesive 114 is a UV glue, which loses its adhesive property when exposed to UV light.

The lower gap-fill layer 116 may encircle the lower integrated circuit dies 100 in a top-down view. The lower gap-fill layer 116 may extend along sidewalls of the lower integrated circuit dies 100 (including the semiconductor substrates 102, the interconnect structure 104, and the dielectric layer 108). The lower gap-fill layer 116 may be formed of a dielectric material, such as silicon oxide, PSG, BSG, BPSG, a TEOS based oxide, polymer, or the like, which may be formed by a suitable deposition process such as CVD, ALD, spin-coating, or the like. Initially, the lower gap-fill layer 116 may cover the covers 109. One or more thinning processes may be performed to level top surfaces of the lower gap-fill layer 116 with top surfaces of the covers 109 and to expose the conductive pads 103. The one or more thinning processes may be a chemical-mechanical polishing (CMP) process, a grinding process, an etch-back process, combinations thereof, or the like. After the one or more thinning processes, the top surfaces of the lower gap-fill layer 116, the covers 109, and the conductive pads 103 may be substantially coplanar or level (within process variations).

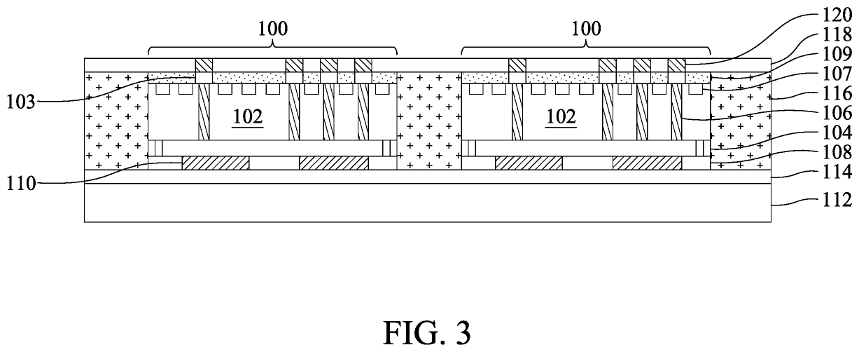

In FIG. 3, a bonding layer 118 is formed on the lower gap-fill layer 116, the covers 109, and the conductive pads 103, and bonding pads 120 are formed in the bonding layer 118. The bonding layer 118 and the bonding pads 120 may be used for bonding with the upper integrated circuit dies in a subsequent process. The bonding pads 120 may extend through the bonding layer 118 to physically and electrically couple to the conductive pads 103. Some of the bonding pads 120 may be physically and electrically isolated from the conductive pads 103, and may be used for bonding purposes. The bonding layer 118 may be formed of an oxide, such as silicon oxide, PSG, BSG, BPSG, a TEOS based oxide, titanium oxide, or the like; or a nitride, such as silicon nitride, silicon oxynitride, silicon carbonitride, aluminum nitride, which may be formed by a suitable deposition process such as CVD, ALD, or the like. The bonding pads 120 may be formed by a damascene process, such as a single damascene process, a dual damascene process, or the like. The bonding pads 120 may be formed of a metal, such as copper, aluminum, or the like, which can be formed by plating or the like. In some embodiments, a planarization process such as a CMP process, a grinding process, an etch-back process, combinations thereof, or the like, is performed on the bonding layer 118 and the bonding pads 120. After the planarization process, top surfaces of the bonding layer 118 and the bonding pads 120 may be substantially coplanar or level (within process variations).

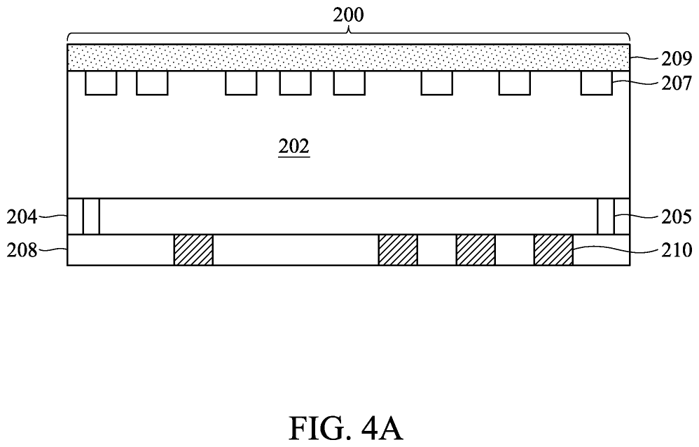

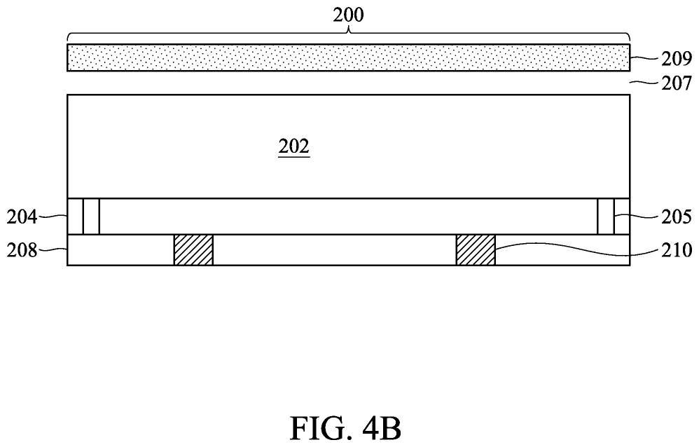

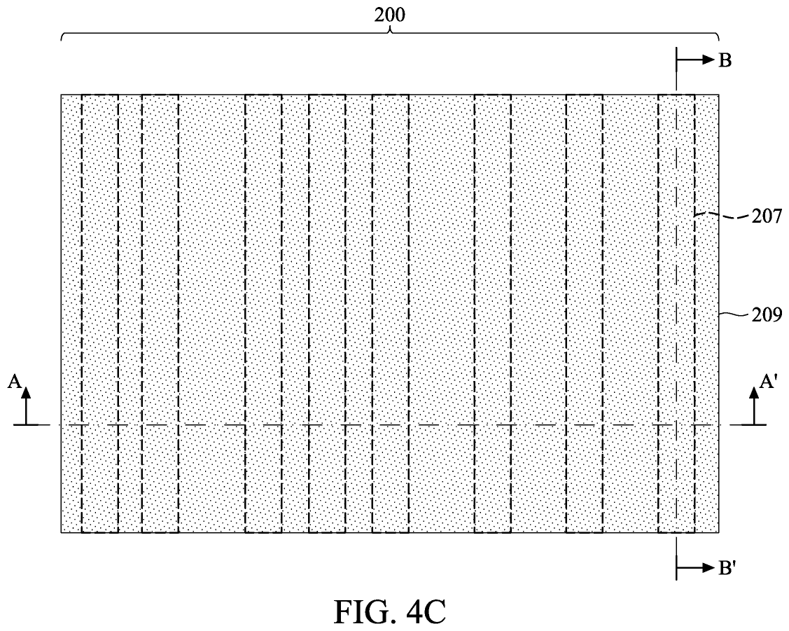

In FIGS. 4A to 4C, an upper integrated circuit die 200 is shown. The cross-sectional view of the upper integrated circuit die 200 shown in FIG. 4A may be obtained along a reference cross-section AA′ shown in the top-down view of the upper integrated circuit die 200 in FIG. 4C. The cross-sectional view of the upper integrated circuit die 200 shown in FIG. 4B may be obtained along a reference cross-section BB′ shown in the top-down view of the upper integrated circuit die 200 in FIG. 4C.

The upper integrated circuit die 200 may be a logic die (e.g., CPU, GPU, SoC, AP, microcontroller, etc.), a memory die (e.g., DRAM die, SRAM die, etc.), a power management die (e.g., PMIC die), a RF die, a sensor die, a MEMS die, a signal processing die (e.g., DSP die), a front-end die (e.g., AFE die), the like, or combinations thereof. The materials and manufacturing processes of the features in the upper integrated circuit die 200 may be same or similar those of the like features in the lower integrated circuit die 100. The upper integrated circuit die 200 may include a semiconductor substrate 202, which may have an active surface (e.g., the surface facing downwards in FIGS. 4A and 4B), which may be called a front side, and an inactive surface (e.g., the surface facing upwards in FIGS. 4A and 4B), which may be called a back side. The back side of the semiconductor substrate 202 may also be referred to as a back side of the upper integrated circuit die 200 and the front side of the semiconductor substrate 202 may face a front side of the upper integrated circuit die 200.

Devices (not separately shown) may be disposed at the active surface of the semiconductor substrate 202. The devices may be active devices (e.g., transistors, diodes, etc.), capacitors, resistors, or the like. The devices may generate a large amount of heat during the operation of the upper integrated circuit die 200 and may create hot-spots in the upper integrated circuit die 200. An interconnect structure 204 may be disposed on the active surface of the semiconductor substrate 202. The interconnect structure 204 may interconnect the devices to form an integrated circuit. The interconnect structure 204 may comprise metallization patterns (not separately shown) in dielectric layers (not separately shown). The metallization patterns may be electrically coupled to the devices. A seal ring 205 may extend through the interconnect structure 204 of the upper integrated circuit die 200. The seal ring 205 may encircle the metallization patterns of the corresponding interconnect structure 204 in the top-down view. The seal ring 205 may be formed of the same or similar material and by the same or similar process as the metallization patterns. The seal ring 205 may be electrically isolated from the devices.

A bonding layer 208 may be disposed on the interconnect structure 204, at the front side of the upper integrated circuit die 200. One or more passivation layer(s) (not separately shown) may be disposed between the bonding layer 208 and the interconnect structure 204. The bonding layer 208 may comprise same or similar materials to the bonding layer 118. Bonding pads 210 may extend through the bonding layer 208 may be electrically coupled to the metallization patterns of the interconnect structure 204. External connections may be made to the upper integrated circuit die 200 through the bonding pads 210. The bonding pads 210 may comprise same or similar materials to the bonding pads 120.

Channels 207 may be disposed on the back side of the semiconductor substrate 202. The channels 207 may be openings in which coolant fluid may travel through to dissipate the heat generated in the upper integrated circuit die 200 during operation, as described in greater detail below. The channels 207 are shown in FIG. 4C in dotted lines for illustrative purposes. As shown in FIGS. 4B and 4C, the channels 207 may extend in parallel through the semiconductor substrate 202 from one sidewall to an opposing sidewall. The channels 207 may be formed in the semiconductor substrate 202 by a suitable photolithography process. The number and arrangement of the channels 207 in FIGS. 4A, 4B, and 4C are provided as examples. Other numbers and arrangements of the channels 207 are also contemplated. A cover 209 may be disposed on the back side of the semiconductor substrate 202 and cover the channels 207. The cover 209 may be adhered to the semiconductor substrate 202 by an adhesive (not separately shown), such as TIM or the like. The cover 209 may be formed of a same or similar material as the semiconductor substrate 202.

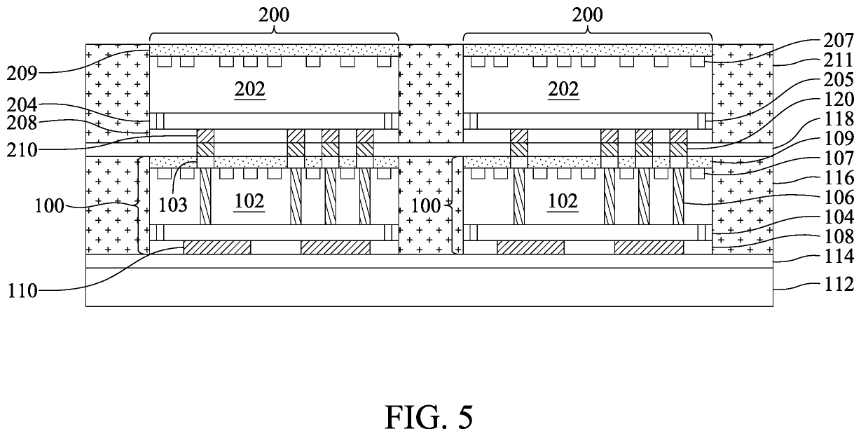

In FIG. 5, the upper integrated circuit dies 200 are bonded to the bonding layer 118 and the bonding pads 120 and an upper gap-fill layer 211 is formed around the upper integrated circuit dies 200. The layout of the upper integrated circuit dies 200 on the bonding layer 118 shown in FIG. 5 is provided as an example. Other layouts of the upper integrated circuit dies 200 are contemplated. The upper integrated circuit dies 200 may be bonded to the bonding layer 118 and the bonding pads 120 by placing the upper integrated circuit dies 200 using a pick-and-place process or the like, then bonding the upper integrated circuit dies 200 to the bonding layer 118 and the bonding pads 120. The bonding layers 208 of the upper integrated circuit dies 200 may be directly bonded to the bonding layer 118 through dielectric-to-dielectric bonding, and the bonding pads 210 of the upper integrated circuit dies 200 may be directly bonded to respective bonding pads 120 through metal-to-metal bonding. In the embodiments illustrated in FIG. 5, the size (e.g., width) of the bonding pads 210 are the same or similar to the respective bonding pads 120. In some embodiments, the size (e.g., width) of the bonding pads 210 is smaller than the respective bonding pads 120.

The bonding process may include a pre-bonding process and an annealing process. During the pre-bonding process, a small pressing force may be applied to press the upper integrated circuit dies 200 against the bonding layer 118 and the bonding pads 120. The pre-bonding process may be performed at a low temperature, such as room temperature. After the pre-bonding process, direct bonds such as dielectric-to-dielectric bonds may be formed between the bonding layers 208 and the bonding layer 118. The bonding strength between the bonding layers 208 and the bonding layer 118 may be then improved in a subsequent annealing process at a higher temperature. The bonding pads 210 may be in contact with the bonding pads 120 after the pre-bonding process, or may expand to be brought into contact with the bonding pads 120 during the annealing process. During the annealing process, the material of the bonding pads 210 may intermingle or bond with the material of the bonding pads 120, so that metal-to-metal bonds may be formed. After the bonding process, the upper integrated circuit dies 200 may be electrically coupled to the lower integrated circuit dies 100 by the bonding pads 120.

The upper gap-fill layer 211 may encircle the upper integrated circuit dies 200 in the top-down view. The upper gap-fill layer 211 may extend along sidewalls of the upper integrated circuit dies 200 (including the semiconductor substrates 202, the interconnect structure 204, and the bonding layer 208). The upper gap-fill layer 211 may be formed by the same or similar method and formed of the same or similar dielectric material as the lower gap-fill layer 116. A thinning process may be performed to remove portions of the upper gap-fill layer 211 and expose the covers 209. The thinning process may be, a CMP process, a grinding process, an etch-back process, combinations thereof, or the like. After the thinning process, top surfaces of the upper gap-fill layer 211 and the covers 209 may be substantially coplanar or level (within process variations).

FIG. 5 illustrates a front-to-back bonding configuration as an example, wherein the back sides of the lower integrated circuit dies 100 face the front sides of the upper integrated circuit dies 200 after bonding. Other bonding configurations may be used, such as a front-to-front bonding configuration or other bonding configuration. In the front-to-front bonding configuration the front sides of lower integrated circuit die 100 may face the front sides of the upper integrated circuit dies 200.

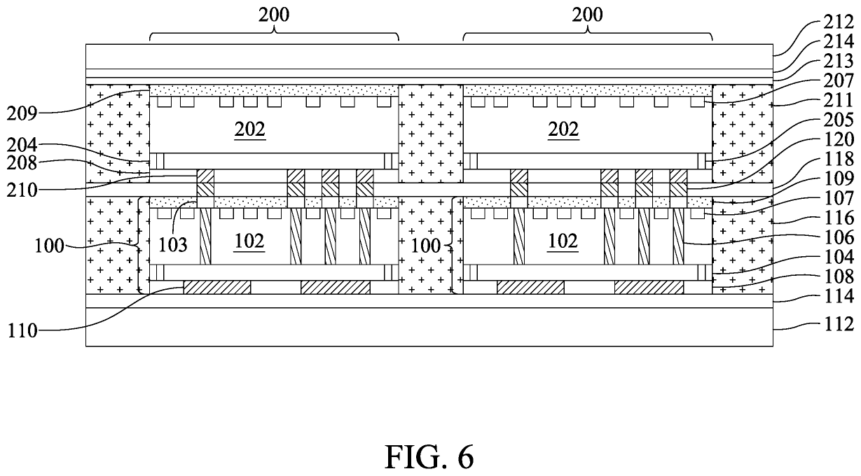

In FIG. 6, a carrier 212 is bonded to the top surfaces of the upper integrated circuit dies 200 and the upper gap-fill layer 211. The carrier 212 may be a semiconductor carrier, a glass carrier, a ceramic carrier, or the like. The carrier 212 may be a wafer having the same or similar size as the carrier 112. In some embodiments, the carrier 212 is bonded to the upper integrated circuit dies 200 and the upper gap-fill layer 211 using bonding layers 213 and 214. The bonding layer 213 may be formed on the covers 209 and the upper gap-fill layer 211, and the bonding layer 214 may be formed on the carrier 212. The bonding layer 213 and the bonding layer 214 may each comprise a dielectric material, such as silicon dioxide or the like, and may be formed by a suitable deposition process such as CVD, ALD, or the like. The structure over the carrier 112 may be bonded to the carrier 212 by bonding the bonding layer 213 and the bonding layer 214 by the same or similar process used for bonding the bonding layer 118 and the bonding layer 208 described with respect to FIG. 5.

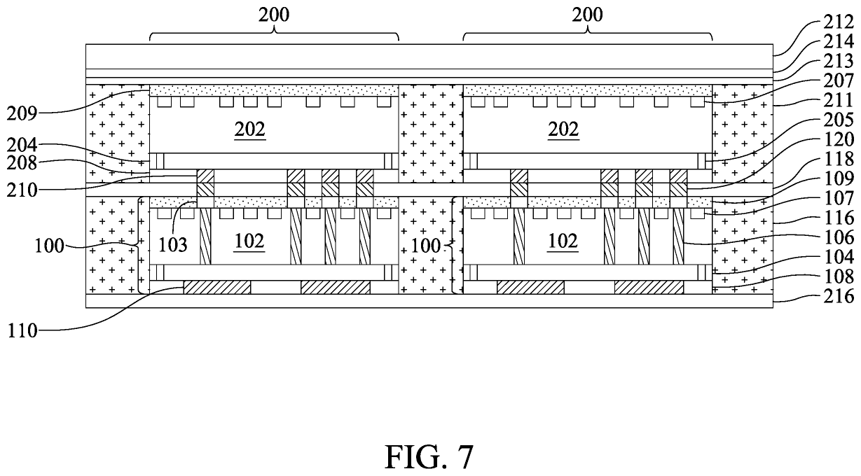

In FIG. 7, the carrier 112 and the adhesive 114 are removed, and a dielectric layer 216 is formed on the lower gap-fill layer 116 and the lower integrated circuit dies 100. The removal process may include projecting a light beam such as a laser beam or a UV light beam on the adhesive 114 (shown in FIG. 6) so that the adhesive 114 may decompose upon exposure to the light beam and the carrier 112 may be removed. In some embodiments, the dielectric layer 216 comprises PBO, polyimide, a BCB-based polymer, or the like, and is formed by a suitable coating process such as spin coating, lamination, or the like. In some embodiments, the dielectric layer 216 comprises silicon dioxide, silicon nitride, or the like, and is formed by a suitable deposition process such as CVD, ALD, or the like. In some embodiments, a redistribution structure (not separately shown) may be formed on the lower gap-fill layer 116 and the lower integrated circuit dies 100 prior to forming the dielectric layer 216 to provide additional routing.

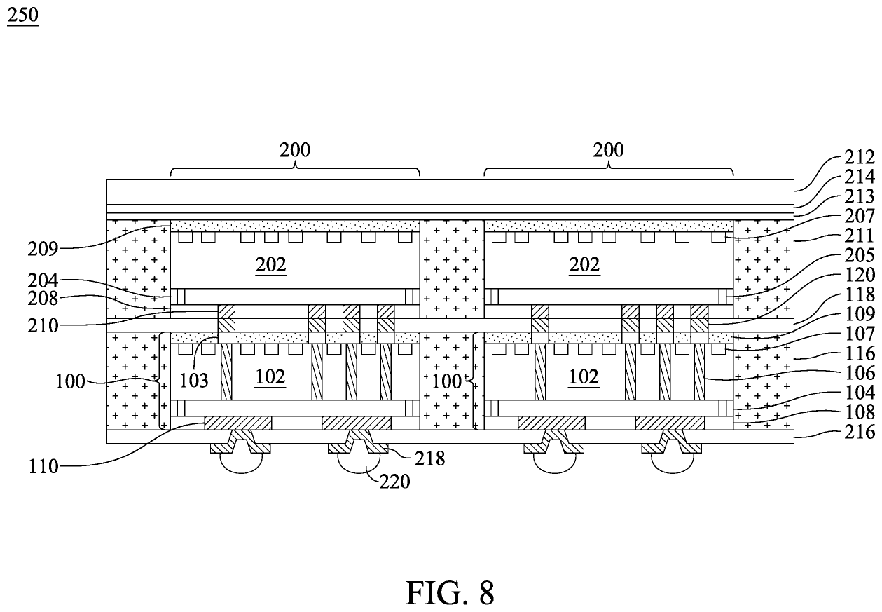

In FIG. 8, under-bump metallizations (UBMs) 218 and electrical connectors 220 are formed. The structure shown in FIG. 8 may be referred to as a wafer structure 250. The UBMs 218 may have portions extending along a surface of the dielectric layer 216 and portions extending through the dielectric layer 216 to physically and electrically couple to the conductive pads 110. As a result, the UBMs 218 are electrically coupled to the lower integrated circuit dies 100. External connections may be made to the lower integrated circuit die 100 through the electrical connectors 220.

To form the UBMs 218, the dielectric layer 216 may be first patterned to form openings exposing the underlying conductive pads 110. The patterning may be done by a suitable photolithography process, such as forming a mask then performing an anisotropic etching. The mask may be removed after the patterning. A seed layer (not separately shown) may be formed on the dielectric layer 216, in the openings through the dielectric layer 216, and on the exposed portions of the conductive pads 110. The seed layer may be formed using a suitable deposition process, such as physical vapor deposition (PVD) or the like. A photoresist may be then formed and patterned on the seed layer. The photoresist may be formed by spin coating or the like and may be exposed to light for patterning. The pattern of the photoresist may correspond to the UBMs 218. The patterning may form openings through the photoresist to expose the seed layer.

A conductive material may be formed in the openings of the photoresist and on the exposed portions of the seed layer. The conductive material may be formed by plating, such as electroless plating, electroplating, or the like. The conductive material may comprise a metal or a metal alloy, such as copper, titanium, tungsten, aluminum, the like, or combinations thereof. Then the photoresist and portions of the seed layer on which the conductive material is not formed may be removed. The photoresist may be removed by an acceptable ashing or stripping process, such as using an oxygen plasma or the like. Once the photoresist is removed, portions of the seed layer on which the conductive material is not formed may be removed by an acceptable etching process, such as by wet or dry etching. The remaining portions of the seed layer and conductive material may form the UBMs 218.

Electrical connectors 220 may be formed on the UBMs 218. The electrical connectors 220 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, the electrical connectors 220 comprise a conductive material such as solder, copper, aluminum, gold, nickel, silver, palladium, tin, the like, or a combination thereof. The electrical connectors 220 may be formed by initially forming a layer of solder through evaporation, electroplating, printing, solder transfer, ball placement, or the like. Once the layer of solder has been formed on the structure, a reflow may be performed to shape the solder into the desired bump shapes. In some embodiments, the electrical connectors 220 comprise metal pillars, such as a copper pillar, formed by a sputtering, printing, electroplating, electroless plating, CVD, or the like, which are free of solder and have substantially vertical sidewalls. A metal cap layer may be formed on top of the metal pillars.

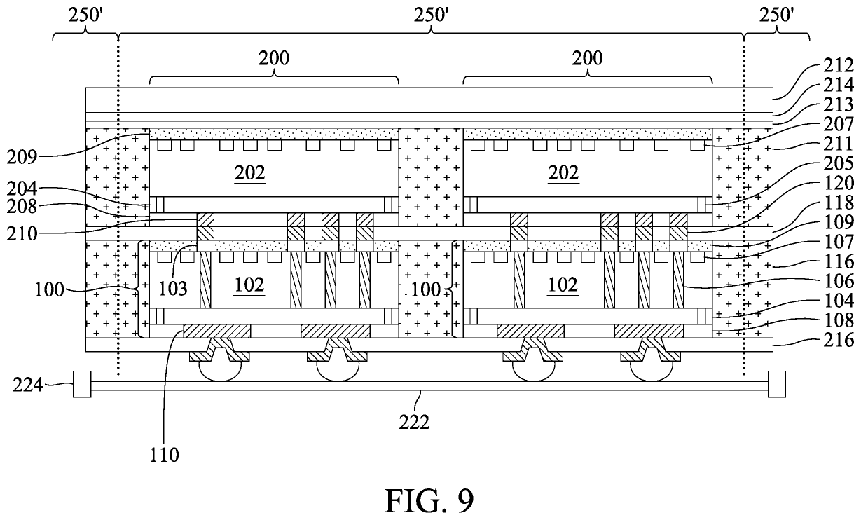

In FIG. 9, the wafer structure 250 is singulated to form individual integrated circuit package components 250′. The processes discussed above may be performed using wafer-level processing. The carrier 212 may be a wafer and may include many structures (not separately shown) similar to the one illustrated in FIG. 8. The wafer structure 250 may be placed on a tape 222 supported by a frame 224. The wafer structure 250 may be then singulated along scribe lines 226, so that the wafer structure 250 may be separated into discrete integrated circuit package components 250′. After the singulation process, the channels 107 in the semiconductor substrates 102 and the channels 207 in the semiconductor substrates 202 may be exposed again on corresponding sidewalls of the semiconductor substrates 102 and the semiconductor substrates 202, as described in greater detail below. The singulation process may include a sawing process, a laser cutting process, or the like. Additional removal process, such as etching or the like, may be performed to remove excess lower gap-fill layer 116 and/or excess upper gap-fill layer 211 that may be blocking the channels 107 and/or the channels 207. A cleaning process or rinsing process may be performed after the singulation process.

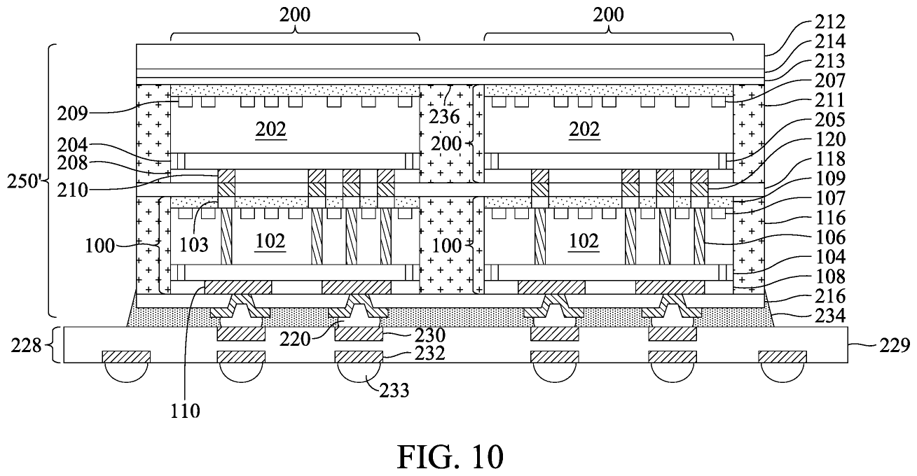

In FIG. 10, the integrated circuit package component 250′ is bonded to a package substrate 228 and an underfill 234 is formed between the integrated circuit package component 250′ and the package substrate 228. The package substrate 228 may comprise a main body 229, conductive pads 230, conductive pads 232, and electrical connectors 233. The package substrate 228 may further comprise conductive features (not separately shown), that electrically couple the conductive pads 230 and the conductive pads 232. In some embodiments, the main body 229 comprises materials such as fiberglass reinforced resin, bismaleimide-triazine (BT) resin, other printed circuit board (PCB) materials, or the like. In some embodiments, the main body 229 comprises materials such as silicon, germanium, silicon germanium, silicon carbide, gallium arsenic, indium arsenide, indium phosphide, silicon germanium carbide, gallium arsenic phosphide, gallium indium phosphide, or the like. The electrical connectors 233 may be formed of the same or similar material and by the same or similar process as the electrical connectors 220. External connections may be made to the package substrate 228 through the electrical connectors 220.

In some embodiments, the package substrate 228 comprises active and/or passive devices (not separately shown), such as transistors, capacitors, resistors, combinations thereof, or the like, and metallization layers (not separately shown) electrically couple the active and/or passive devices to the conductive pads 230 and the conductive pads 232. The metallization layers may be alternating layers of dielectric material (e.g., low-k dielectric material) and conductive material (e.g., copper) with vias interconnecting the layers of conductive material. In some embodiments, the package substrate 228 is free of active and/or passive devices.

During the bonding process the electrical connectors 220 may be reflowed to bond the integrated circuit package component 250′ to the conductive pads 230. The electrical connectors 220 may physically and electrically couple the package substrate 228 to the integrated circuit package component 250′. In some embodiments, a solder resist (not separately shown) is formed on the package substrate 228. The electrical connectors 220 may be disposed in openings in the solder resist to physically and electrically couple to the conductive pads 230. The solder resist may be used to protect areas of the package substrate 228 from external damage. The underfill 234 may surround the electrical connectors 220 and protect the joints resulting from the reflowing of the electrical connectors 220. The underfill 234 may encircle the integrated circuit package component 250′ in the top-down view. The underfill 234 may be formed by a capillary flow process after the integrated circuit package component 250′ is attached or by a suitable deposition method before the integrated circuit package component 250′ is bonded. The underfill 234 may be subsequently cured.

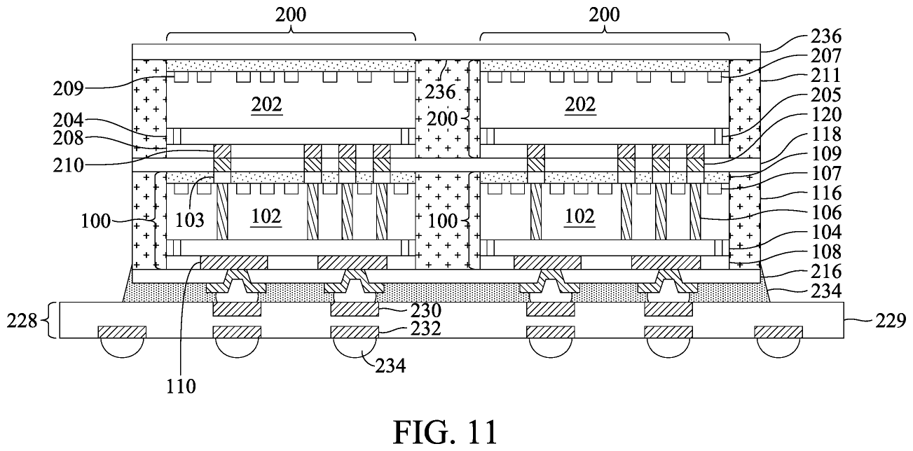

In FIG. 11, the bonding layers 213 and 214 are removed and an adhesive layer 236 is formed on the upper gap-fill layer 211 and the upper integrated circuit dies 200. The bonding layers 213 and 214 may be removed by a CMP process, a grinding process, an etch-back process, combinations thereof, or the like. The adhesive layer 236 may be used to adhere a lid to the structure shown in Figure ii while dissipating the heat generated by the upper integrated circuit dies 200 and the lower integrated circuit dies 100 to the lid during operation. The adhesive layer 236 may comprise a thermal interface material (TIM), which may be a material with high thermal conductivity, such as, thermal paste, gel-based thermal adhesive, graphite, graphene film, the like, or the combinations thereof.

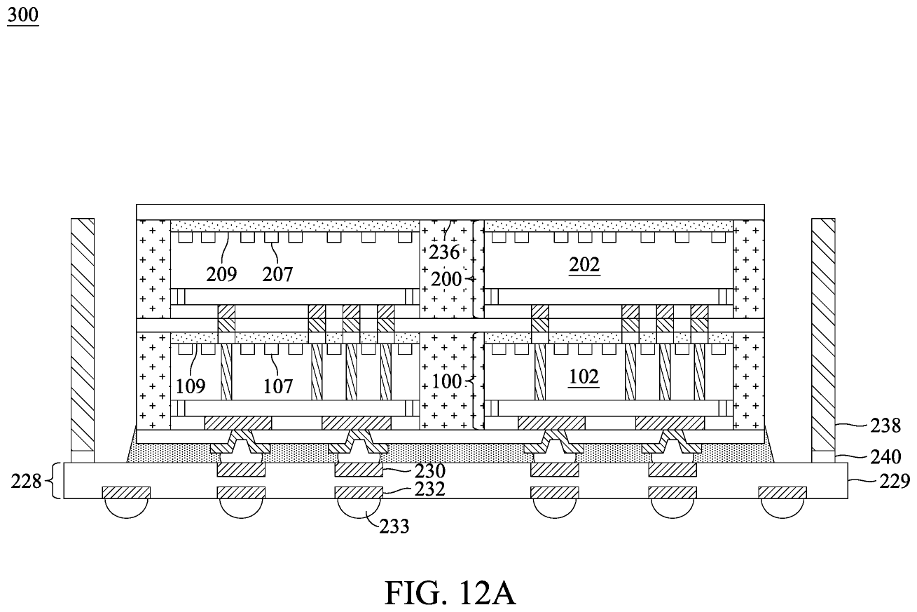

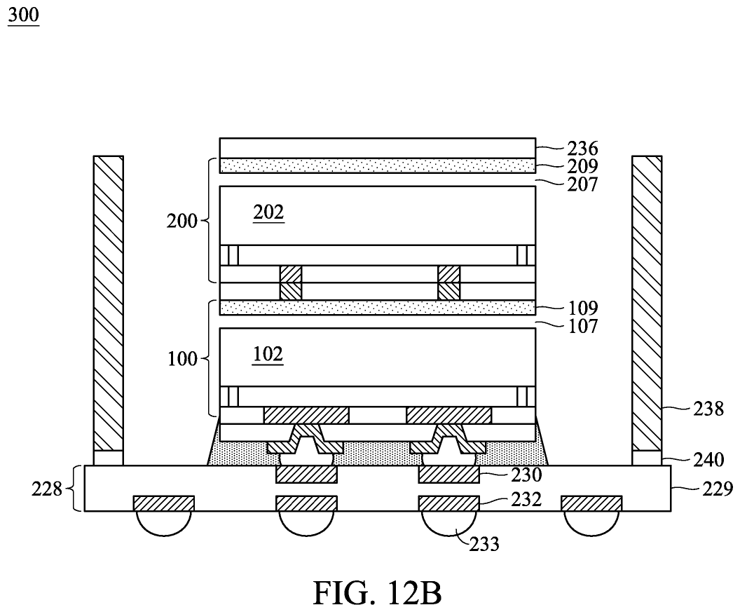

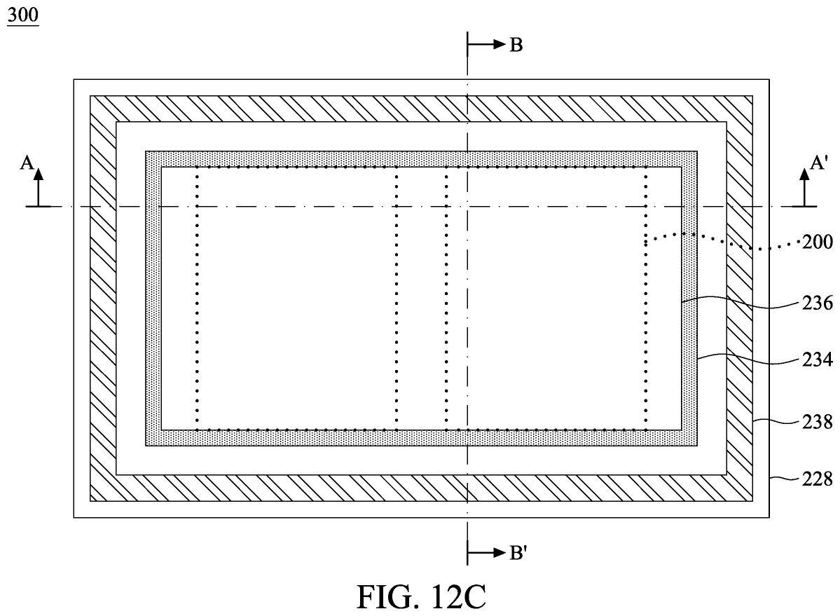

In FIGS. 12A, 12B, and 12C, a stiffener ring 238 is attached to the package substrate 228. The structure shown in FIGS. 12A, 12B, and 12C may be referred to as an integrated circuit package component 300. The cross-sectional view of the integrated circuit package component 300 shown in FIG. 12A may be obtained along a reference cross-section AA′ shown in the top-down view of the integrated circuit package component 300 in FIG. 12C. The cross-sectional view of the integrated circuit package component 300 shown in FIG. 12B may be obtained along a reference cross-section BB′ shown in the top-down view of the integrated circuit package component 300 in FIG. 12C. The upper integrated circuit dies 200 are shown in FIG. 12C in dotted lines for illustrative purposes.

The stiffener ring 238 may be used to provide additional support to the package substrate 228 during subsequent manufacturing processes to reduce warpage or other types of deformation of the package substrate 228. The stiffener ring 238 may also be used to provide support to a lid that may be attached to the integrated circuit package component 300 in a subsequent process. The stiffener ring 238 may be formed of a material with a large hardness, such as a metal, metal alloy, or the like. The stiffener ring 238 may be attached to the package substrate 228 by an adhesive 240, such as an epoxy, glue, or the like. As shown in FIG. 12B, in the integrated circuit package component 300, the channels 107 in the semiconductor substrates 102 of the lower integrated circuit dies 100 and the channels 207 in the semiconductor substrates 202 of the upper integrated circuit dies 200 may be exposed on corresponding sidewalls of the semiconductor substrates 102 and the semiconductor substrates 202. The channels 107 and the channels 207 may be connected to corresponding channels in the lid that may be attached to the integrated circuit package component 300 in a subsequent process, as described in greater detail below.

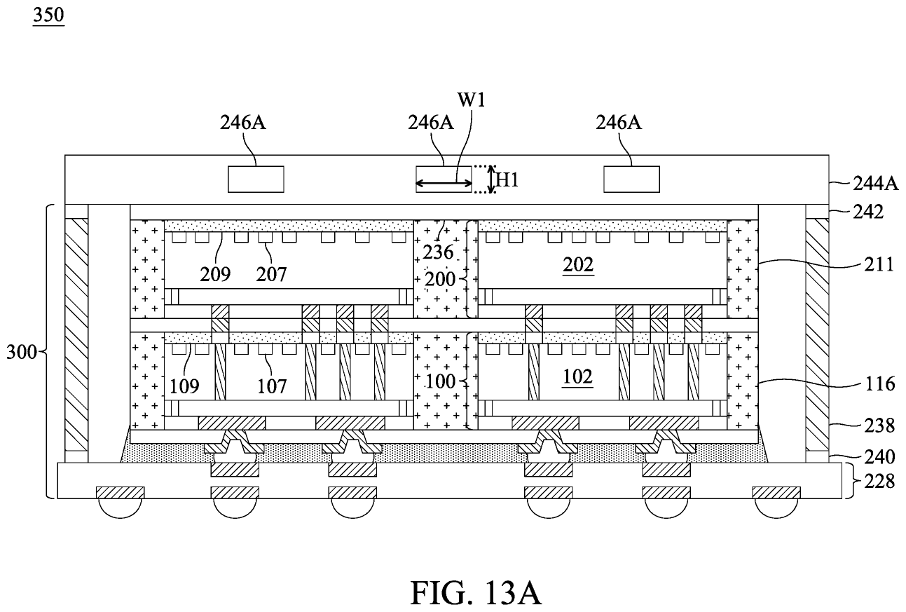

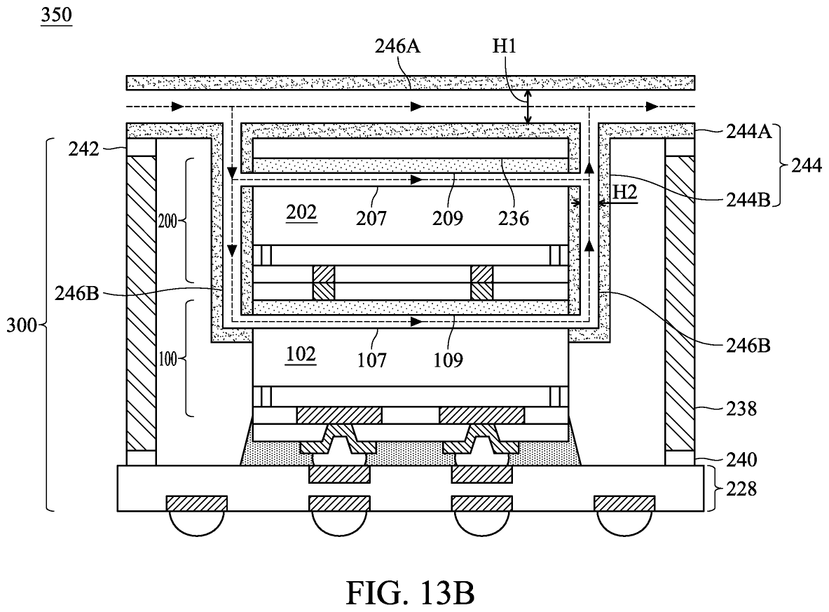

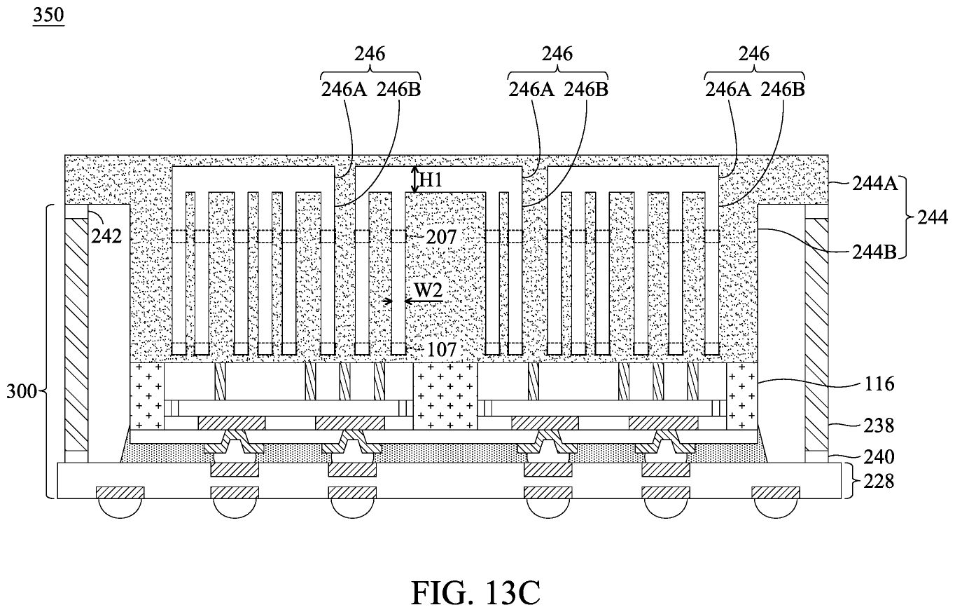

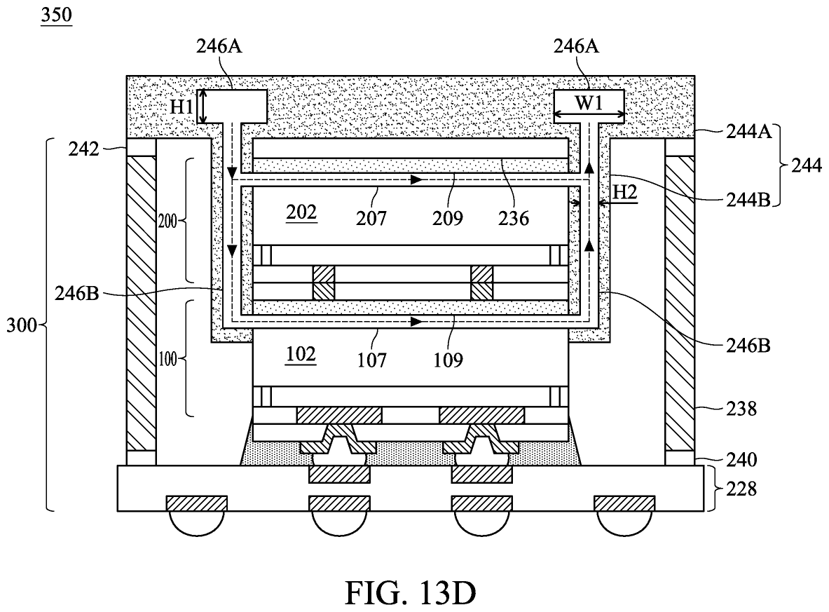

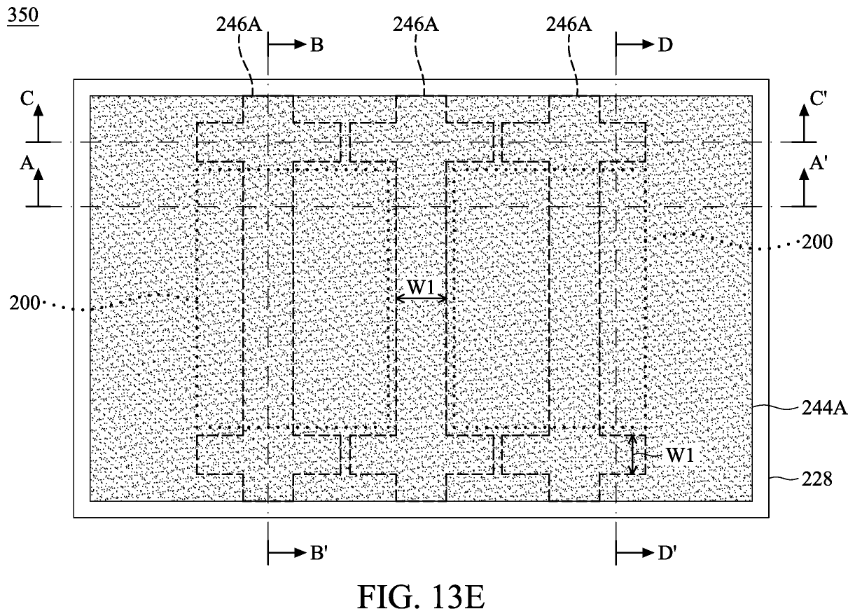

In FIGS. 13A, 13B, 13C, 13D, and 13E, a lid 244 is attached to the integrated circuit package component 300. The structure shown in FIGS. 13A, 13B, 13C, 13D, and 13E may be referred to as an integrated circuit package 350. The cross-sectional view of the integrated circuit package 350 shown in FIG. 13A may be obtained along a reference cross-section AA′ shown in the top-down view of the integrated circuit package 350 in FIG. 13E. The cross-sectional view of the integrated circuit package 350 shown in FIG. 13B may be obtained along a reference cross-section BB′ shown in the top-down view of the integrated circuit package 350 in FIG. 13E. The cross-sectional view of the integrated circuit package 350 shown in FIG. 13C may be obtained along a reference cross-section CC′ shown in the top-down view of the integrated circuit package 350 in FIG. 13E. The cross-sectional view of the integrated circuit package 350 shown in FIG. 13D may be obtained along a reference cross-section DD′ shown in the top-down view of the integrated circuit package 350 in FIG. 13E. The upper integrated circuit dies 200 are shown in FIG. 13E in dotted lines for illustrative purposes.

The lid 244 may comprise a top portion 244A and two bottom portions 244B. The top portion 244A may be attached to the upper integrated circuit dies 200 and the upper gap-fill layer 211 by the adhesive layer 236 as well as to the stiffener ring 238 by an adhesive 242, such as an epoxy, glue, or the like. The bottom portions 244B may protrude from a bottom surface of the top portion 244A and extend along sidewalls of the upper integrated circuit dies 200 (including the sidewalls of the semiconductor substrates 202) as well as sidewalls of the lower integrated circuit dies 100 (including the sidewalls of the semiconductor substrates 102). In the embodiments shown in FIGS. 13B and 13D, the bottom portions 244B are in contact with the sidewalls of the upper integrated circuit dies 200 and the sidewalls of the lower integrated circuit dies 100.

The lid 244 may comprise top channels 246A in the top portion 244A and bottom channels 246B in the bottom portions 244B. The top channels 246A and bottom channels 246B may be openings in which coolant fluid may travel through to flow into the channels 107 of the lower integrated circuit dies 100 and the channels 207 of the upper integrated circuit dies 200, as described in greater detail below. The top channels 246A are shown in FIG. 13E in dotted lines for illustrative purposes. The channels 107 and the channels 207 are shown in FIG. 13C in dotted lines for illustrative purposes. As shown in FIGS. 13A, 13B, 13C, and 13D, the top channels 246A may extend horizontally in the top portion 244A of the lid 244. As shown in FIG. 13E, each top channel 246A may have a shape of a double-dagger with a main portion extending through the top portion 244A and side portions extending along the sidewalls of the upper integrated circuit dies 200.

As shown in FIGS. 13B, 13C, and 13D, each bottom channel 246B may have a shape of an inverted “F” and may extend vertically and horizontally in the bottom portions 244B of the lid 244. Vertical portions of the bottom channels 246B may be connected to the top channels 246A. Horizontal portions of the bottom channels 246B may extend through inner sidewalls of the bottom portions 244B and may be connected to the channels 107 of the lower integrated circuit dies 100 and the channels 207 of the upper integrated circuit dies 200. In the embodiments shown in FIGS. 13B, 13C, and 13D, the number of the bottom channels 246B may correspond to a total number of the channels 107 and a total number of the channels 207, and each bottom channel 246B is connected to a channel 107 and a channel 207.

The lid 244 may be formed of a metal or a metal alloy, such as copper, stainless steel, or the like. The top channels 246A and the bottom channels 246B may be formed by a suitable machining process. A cross-section of the main portion or the side portion of the top channel 246A may be a rectangle with a height H1 in a range from about 5 mm to about 30 mm and a width W1 in a range from about 5 mm to about 30 mm. A cross-section of the vertical portion of the bottom channel 246B may be a rectangle with a height H2 in a range from about 1 μm to about 100 μm and a width W2 in a range from about 1 μm to about 100 μm. In some embodiments, the height H1 is larger than height H2, and the width W1 is larger than the width W2. In some embodiments, the shape and size of a cross-section of the each horizontal portion of the bottom channels 246B is the same or similar to the shape and size of a cross-section of the corresponding channel 107 or channel 207.

FIGS. 13B and 13D illustrate an example of the flow pathway of the coolant fluid during the operation of the integrated circuit package 350. The coolant fluid may flow into the top portion 244A of the lid 244 from one end of each top channel 246A. The coolant fluid may flow through the main portion of the top channel 246A and flow out of the top portion 244A from the other end of the top channel 246A while the heat transferred to the adhesive layer 236 from the lower integrated circuit dies 100 and the upper integrated circuit dies 200 may be dissipated to the coolant fluid. The coolant fluid may also flow directly downward into the bottom channel 246B connected to the main portion of the top channel 246A or first into the side portions of the top channel 246A then downward to the bottom channels 246B connected to the side portions of the top channel 246A. Such bottom channels 246B may be in one bottom portion 244B of the lid 244. Then the coolant fluid may flow through the corresponding channels 107 and channels 207 connected to the bottom channels 246B while the heat generated in the lower integrated circuit dies 100 and the upper integrated circuit dies 200 may be dissipated to the coolant fluid. Afterwards, the coolant fluid may flow into the bottom channels 246B in the other bottom portion 244B of the lid 244, and back to the top channel 246A before flowing out of the top portion 244A.

Since the coolant fluid that flows through the bottom channels 246B, the channels 107, and the channels 207 are closer to the hot-spots (e.g., devices) in the lower integrated circuit dies 100 and the upper integrated circuit dies 200, the heat generated in the lower integrated circuit dies 100 and the upper integrated circuit dies 200 may be more effectively dissipated during the operation of the integrated circuit package 350, thereby improving the heat dissipation of the integrated circuit package 350. As a result, the performance and reliability of the integrated circuit package 350 may be improved.

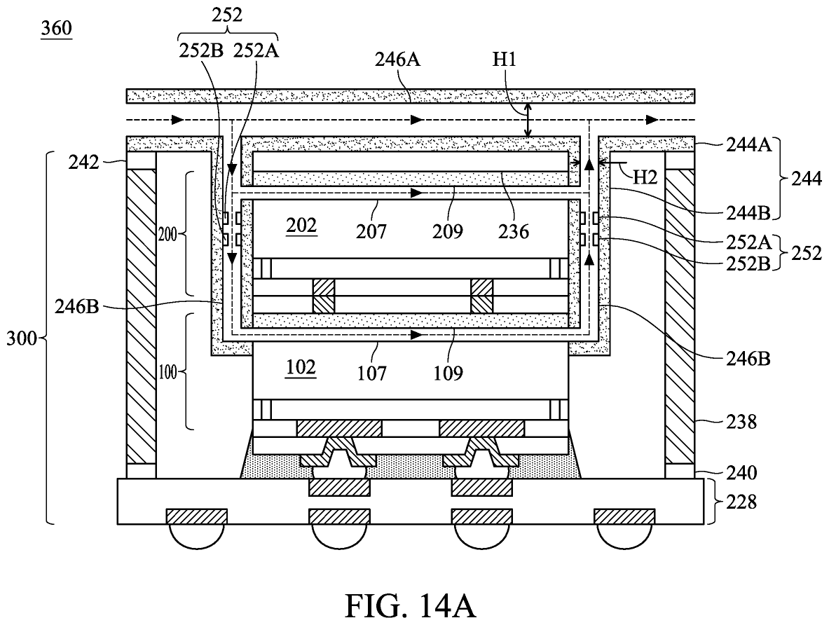

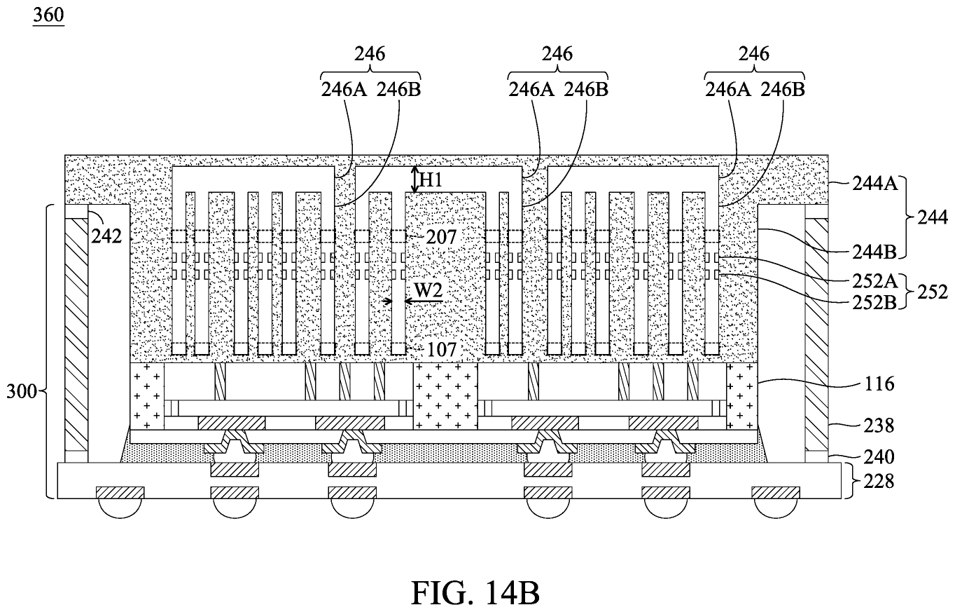

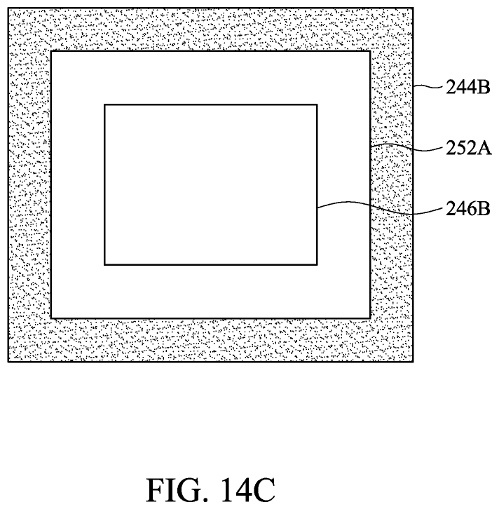

FIGS. 14A and 14B show an integrated circuit package 360 similar to the integrated circuit package 350 shown in FIGS. 13B and 13C, in accordance with some embodiments, wherein like features refer to like features formed by like processes. In the integrated circuit package 360, the lid 244 may comprise one or more pumps 252, such as electrohydrodynamic (EHD) pumps, in the top channels 246A and/or the bottom channels 246B. The pumps 252 may propel the flow of the coolant fluid in the top channels 246A and/or the bottom channels 246B. The pumps 252 may be powered by an external power source (not separately shown).

In the embodiments shown in FIGS. 14A and 14B, the pumps 252 are EHD pumps, each of which comprise an electrode 252A and an electrode 252B, and the coolant fluid is a fluid comprising ions, such as water. An electrical field may be created between the electrode 252A and the electrode 252B, which may propel the flow of the ionized coolant fluid in the bottom channels 246B. The electrode 252A and the electrode 252B may be electrically isolated from the lid 244. FIGS. 14A and 14B show one pump 252 disposed in each bottom channel 246B as an example. In some embodiments, more than one pump 252 may be disposed in each bottom channel 246B. FIG. 14C shows a top-down view of the electrode 252A with a part of the surrounding bottom portion 244B of the lid 244. The electrode 252A may have a shape of a frame or a ring with an opening in the center, which may be a part of the bottom channel 246B. The electrode 252A and the electrode 252B may have the same or similar sizes and shapes.

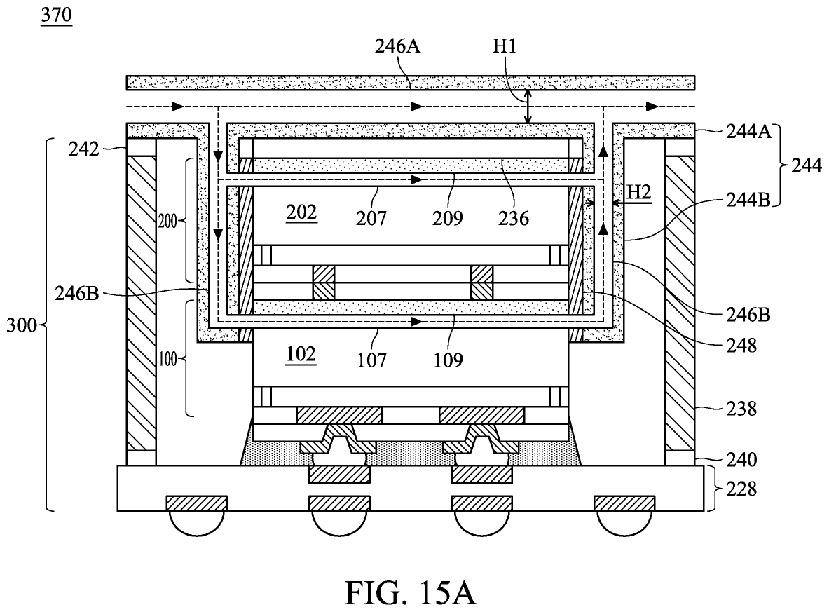

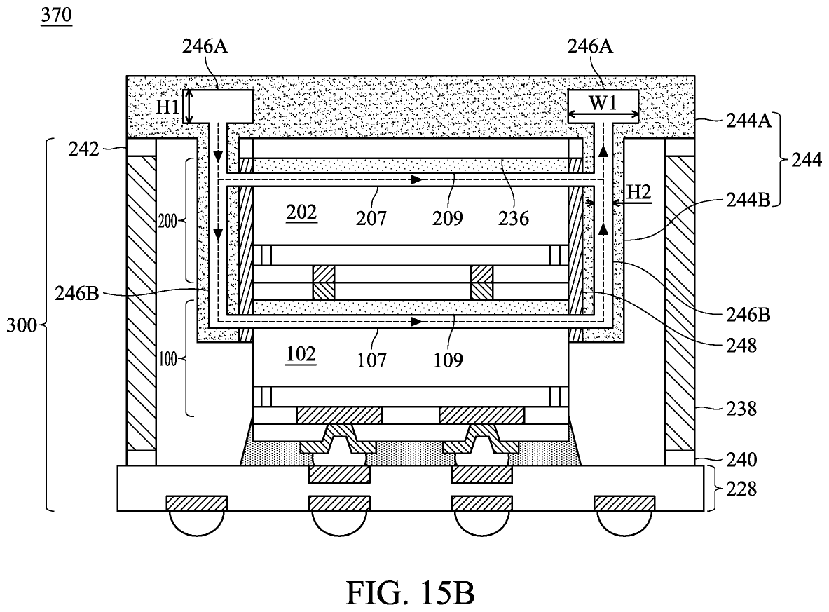

FIGS. 15A and 15B show an integrated circuit package 370 similar to the integrated circuit package 350 shown in FIGS. 13B and 13D, in accordance with some embodiments, wherein like features refer to like features formed by like processes. In the integrated circuit package 370, the bottom portions 244B are adhered to the sidewalls of the upper integrated circuit dies 200 and the sidewalls of the lower integrated circuit dies 100 by an adhesive 248, which may comprise a same or similar material as the adhesive layer 236. The pumps 252, such as EHD pumps, discussed with respect to FIGS. 14A, 14B, and 14C may be also added to the top channels 246A and/or the bottom channels 246B of the lid 244 in the integrated circuit package 370.

Various embodiments are described above in the context of a system on integrated chips (SoIC) package configuration. It should be understood that various embodiments may also be adapted to apply to other package configurations, such as integrated fan-out on substrate (InFO), chip on wafer on substrate (CoWoS) or the like.

The embodiments may have some advantageous features. By using the lid 244 comprising the top channels 246A and the bottom channels 246B in the integrated circuit package 350, the heat generated in the lower integrated circuit dies 100 and the upper integrated circuit dies 200 may be more effectively dissipated during the operation of the integrated circuit package 350, thereby improving the heat dissipation of the integrated circuit package 350. As a result, the performance and reliability of the integrated circuit package 350 may be improved.

In an embodiment, an integrated circuit package includes a first die over a package substrate, wherein the first die includes a first substrate, and wherein a first channel extends through the first substrate from a first sidewall of the first die to a second sidewall of the first die; and a lid, including: a top portion over the first die; and a first bottom portion extending along the first sidewall of the first die, wherein the first bottom portion includes a second channel, and wherein the second channel is connected to the first channel. In an embodiment, the top portion of the lid further includes a third channel, and wherein the third channel is connected to the second channel. In an embodiment, the third channel has a larger width than the second channel. In an embodiment, the lid further includes a second bottom portion extending along the second sidewall of the first die, wherein the second bottom portion includes a third channel, and wherein the third channel is connected to the first channel. In an embodiment, the integrated circuit package further includes a second die between the first die and the package substrate, wherein the second die is electrically connected to the first die and the package substrate, wherein the second die includes a second substrate, wherein a third channel extends through the second substrate from a first sidewall of the second die to a second sidewall of the second die, and wherein the first bottom portion of the lid extends along the first sidewall of the second die. In an embodiment, second channel is connected to the third channel. In an embodiment, the lid further includes an electrohydrodynamic (EHD) pump in the second channel.

In an embodiment, an integrated circuit package includes a first die over a package substrate, wherein the first die includes a first substrate; and a lid, including: a top portion over the first die; a first bottom portion extending along a first sidewall of the first die, wherein the first bottom portion includes a first fluid channel; and a second bottom portion extending along a second sidewall of the first die, wherein the second sidewall of the first die opposes the first sidewall of the first die, and wherein the second bottom portion includes a second fluid channel. In an embodiment, the top portion of the lid further includes a third fluid channel, and wherein the third fluid channel connects the first fluid channel and the second fluid channel. In an embodiment, the first substrate includes a third fluid channel, and wherein the third fluid channel connects the first fluid channel and the second fluid channel. In an embodiment, the first die further includes a first cover between the first substrate and the lid, and wherein the third fluid channel is between a bottom surface of the first cover and an upper surface of the first substrate. In an embodiment, the integrated circuit package further includes a second die between the first die and the package substrate, wherein the second die is electrically connected to the first die and the package substrate, wherein the second die includes a second substrate, wherein the first bottom portion of the lid extends along a first sidewall of the second die, wherein the second bottom portion of the lid extends along a second sidewall of the second die, and wherein the second sidewall of the second die opposes the first sidewall of the second die. In an embodiment, the second substrate includes a third fluid channel, and wherein the third fluid channel connects the first fluid channel and the second fluid channel. In an embodiment, the first bottom portion of the lid is adhered to the first sidewall of the first die by an adhesive.

In an embodiment, a method of forming an integrated circuit package includes bonding a first die to a package substrate; attaching a stiffener ring to the package substrate, wherein the stiffener ring encircles the first die in a top-down view; and attaching a lid to the stiffener ring, the lid including: a top portion over the first die, wherein the top portion of the lid further includes a first fluid channel; a first bottom portion protruding from a bottom surface of the top portion, wherein the first bottom portion extends along a first sidewall of the first die, wherein the first bottom portion includes a second fluid channel; and a second bottom portion protruding from the bottom surface of the top portion, wherein the second bottom portion extends along a second sidewall of the first die, wherein the second sidewall of the first die opposes the first sidewall of the first die, and wherein the second bottom portion includes a third fluid channel. In an embodiment, the first fluid channel is connected to the second fluid channel and the third fluid channel. In an embodiment, the first die includes a first substrate, wherein a fourth fluid channel extends through the first substrate, and wherein the fourth fluid channel is connected to the second fluid channel and the third fluid channel. In an embodiment, the method further includes bonding a second die over the first die before attaching the lid, wherein the first die electrically connect the second die and the package substrate, wherein the first bottom portion of the lid extends along a first sidewall of the second die, wherein the second bottom portion of the lid extends along a second sidewall of the second die, wherein the second sidewall of the second die opposes the first sidewall of the second die. In an embodiment, the first die includes a first substrate and the second die includes a second substrate, wherein a fourth fluid channel extends through the first substrate and a fifth fluid channel extends through the second substrate, wherein the second fluid channel is connected to the fourth fluid channel and the fifth fluid channel, and wherein the third fluid channel is connected to the fourth fluid channel and the fifth fluid channel. In an embodiment, the lid further includes one or more electrohydrodynamic (EHD) pumps in the second fluid channel and one or more EHD pumps in the third fluid channel.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit package, comprising:
a first die over a package substrate, wherein the first die comprises a first substrate, and wherein a first channel extends through the first substrate from a first sidewall of the first die to a second sidewall of the first die; and
a lid, comprising:
a top portion over the first die; and
a first bottom portion extending along the first sidewall of the first die, wherein the first bottom portion comprises a second channel, and wherein the second channel is connected to the first channel.

2. The integrated circuit package of claim 1, wherein the top portion of the lid further comprises a third channel, and wherein the third channel is connected to the second channel.

3. The integrated circuit package of claim 2, wherein the third channel has a larger width than the second channel.

4. The integrated circuit package of claim 1, wherein the lid further comprises a second bottom portion extending along the second sidewall of the first die, wherein the second bottom portion comprises a third channel, and wherein the third channel is connected to the first channel.

5. The integrated circuit package of claim 1, further comprising a second die between the first die and the package substrate, wherein the second die is electrically connected to the first die and the package substrate, wherein the second die comprises a second substrate, wherein a third channel extends through the second substrate from a first sidewall of the second die to a second sidewall of the second die, and wherein the first bottom portion of the lid extends along the first sidewall of the second die.

6. The integrated circuit package of claim 5, wherein second channel is connected to the third channel.

7. The integrated circuit package of claim 1, wherein the lid further comprises an electrohydrodynamic (EHD) pump in the second channel.

8. An integrated circuit package, comprising:
a first die over a package substrate, wherein the first die comprises a first substrate; and
a lid, comprising:
a top portion over the first die;
a first bottom portion extending along a first sidewall of the first die, wherein the first bottom portion comprises a first fluid channel; and
a second bottom portion extending along a second sidewall of the first die, wherein the second sidewall of the first die opposes the first sidewall of the first die, and wherein the second bottom portion comprises a second fluid channel.

9. The integrated circuit package of claim 8, wherein the top portion of the lid further comprises a third fluid channel, and wherein the third fluid channel connects the first fluid channel and the second fluid channel.

10. The integrated circuit package of claim 8, wherein the first substrate comprises a third fluid channel, and wherein the third fluid channel connects the first fluid channel and the second fluid channel.

11. The integrated circuit package of claim 10, wherein the first die further comprises a first cover between the first substrate and the lid, and wherein the third fluid channel is between a bottom surface of the first cover and an upper surface of the first substrate.

12. The integrated circuit package of claim 8, further comprising a second die between the first die and the package substrate, wherein the second die is electrically connected to the first die and the package substrate, wherein the second die comprises a second substrate, wherein the first bottom portion of the lid extends along a first sidewall of the second die, wherein the second bottom portion of the lid extends along a second sidewall of the second die, and wherein the second sidewall of the second die opposes the first sidewall of the second die.

13. The integrated circuit package of claim 12, wherein the second substrate comprises a third fluid channel, and wherein the third fluid channel connects the first fluid channel and the second fluid channel.

14. The integrated circuit package of claim 8, wherein the first bottom portion of the lid is adhered to the first sidewall of the first die by an adhesive.

15. A method of forming an integrated circuit package, the method comprising:
bonding a first die to a package substrate;
attaching a stiffener ring to the package substrate, wherein the stiffener ring encircles the first die in a top-down view; and
attaching a lid to the stiffener ring, the lid comprising:
a top portion over the first die, wherein the top portion of the lid further comprises a first fluid channel;
a first bottom portion protruding from a bottom surface of the top portion, wherein the first bottom portion extends along a first sidewall of the first die, wherein the first bottom portion comprises a second fluid channel; and
a second bottom portion protruding from the bottom surface of the top portion, wherein the second bottom portion extends along a second sidewall of the first die, wherein the second sidewall of the first die opposes the first sidewall of the first die, and wherein the second bottom portion comprises a third fluid channel.

16. The method of claim 15, wherein the first fluid channel is connected to the second fluid channel and the third fluid channel.

17. The method of claim 15, wherein the first die comprises a first substrate, wherein a fourth fluid channel extends through the first substrate, and wherein the fourth fluid channel is connected to the second fluid channel and the third fluid channel.

18. The method of claim 15, further comprising bonding a second die over the first die before attaching the lid, wherein the first die electrically connect the second die and the package substrate, wherein the first bottom portion of the lid extends along a first sidewall of the second die, wherein the second bottom portion of the lid extends along a second sidewall of the second die, wherein the second sidewall of the second die opposes the first sidewall of the second die.

19. The method of claim 18, wherein the first die comprises a first substrate and the second die comprises a second substrate, wherein a fourth fluid channel extends through the first substrate and a fifth fluid channel extends through the second substrate, wherein the second fluid channel is connected to the fourth fluid channel and the fifth fluid channel, and wherein the third fluid channel is connected to the fourth fluid channel and the fifth fluid channel.

20. The method of claim 15, wherein the lid further comprises one or more electrohydrodynamic (EHD) pumps in the second fluid channel and one or more EHD pumps in the third fluid channel.
